(19) United States
(12) Patent Application Publication
(10) Pub. No.: US 2013/0255773 A1
(43) Pub. Date: Oct. 3, 2013

(54) PHOTOVOLTAIC CELL AND METHODS FOR MANUFACTURE

(71) Applicant: NUSOLA, INC., Burlingame, CA (US)

(72) Inventors: Koji Matsumaru, Nagaoka-Shi (JP); Jose Briceno, Tokyo-to (JP)

(21) Appl. No.: 13/844,428

(22) Filed: Mar. 15, 2013

Related U.S. Application Data
(60) Provisional application No. 61/722,693, filed on Nov. 5, 2012.
(60) Provisional application No. 61/655,449, filed on Jun. 4, 2012.
(60) Provisional application No. 61/619,410, filed on Apr. 2, 2012.

(51) Int. Cl. H01L 31/18; H01L 31/0352

(52) U.S. Cl. CPC H01L 31/1804; H01L 31/035272
USPC 136/256; 438/89

(57) ABSTRACT

A material is manufactured from a single piece of semiconductor material. The material manufactured includes a top layer of a semiconductor compound and a bottom layer of a semiconductor bulk. The material may also have an intrinsic semiconductor layer. The material is created from a transformative process on the single-piece semiconductor material caused by heating a semiconductor material having an impurity under particular conditions. The material manufactured exhibits photovoltaic properties because the layers formed during the transformative process create a p-i-n, a p-n, or an n-n junction having a band-gap difference between the n-type layers.

### CROSS-REFERENCE TO RELATED APPLICATIONS

This application claims the benefit of U.S. Provisional Application No. 61/722,693, entitled “Photovoltaic Cell and Methods of Manufacture,” filed on Nov. 5, 2012 (Ref. No. P3), U.S. Provisional Application No. 61/655,449, entitled “Structure For Creating Ohmic Contact In Semiconductor Devices And Methods for Manufacture,” filed on Jun. 4, 2012 (Ref. No. P4), and U.S. Provisional Application No. 61/619,410, entitled “Single-Piece Photovoltaic Structure,” filed on Apr. 2, 2012 (Ref. No. P2), the entireties of which are incorporated by reference as if fully set forth herein.

This application is related to copending U.S. application Ser. No. 13/844,298, “Single-Piece Photovoltaic Structure,” filed on even date herewith (Ref. No. P2), and U.S. application Ser. No. 13/______, “Single-Piece Photovoltaic Structure,” filed on even date herewith (Ref. No. P4), the entireties of which are incorporated by reference as if fully set forth herein.

### FIELD OF THE INVENTION

The present invention relates to manufacturing photovoltaic materials from a semiconductor material, and in particular, a new material manufactured from a single piece of semiconductor material.

### BACKGROUND OF THE INVENTION

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Conventional methods for manufacturing photovoltaic materials typically require some additives to a semiconductor. Such additives, including gallium arsenide (GaAs), can be highly toxic and carcinogenic, and their use in the manufacturing process of photovoltaic materials can increase the risk of negative health and environmental effects. It is highly desirable to have a manufacturing process of photovoltaic material with reduced use of additives.

The conventional methods for manufacturing photovoltaic materials also require a multi-step process, or different processes, with each step possibly taking place at a different apparatus and at different times, and requiring its own management and resources. For instance, different doping processes are applied to manufacture different semiconductor wafers, and the wafers of different types are sealed together in a particular way to form a photovoltaic material. The purpose for the doping processes and assembly of the wafers is to create p-n junctions, or p-i-n junctions, in between wafers to achieve an overall photovoltaic effect in the assembled material. In other conventional methods, different layers are successively formed by a executing a separate deposition process for each layer. Another example of an additional manufacturing process executed in forming photovoltaic is texturing. Each of such manufacturing stages incurs a cost. It is highly desirable to have a manufacturing process for photovoltaic material that reduces the number of necessary processes or steps to reduce costs.

### BRIEF SUMMARY OF PREFERRED EMBODIMENTS OF THE INVENTION

A new material manufactured from a single piece of semiconductor material is described. Techniques are provided for manufacturing a new material from a single piece of semiconductor material. In some embodiments, the manufacture of the material does not require multiple uses of toxic additives and doping processes, and does not require the assembly of different types semiconductor wafers or formation of multiple semiconductor layers by executing separate processes for each layer.

### BRIEF DESCRIPTION OF THE DRAWINGS

Preferred embodiments of the present invention is illustrated by way of example, and not by way of limitation, in the figures of the accompanying drawings and in which like reference numerals refer to similar elements and in which:

FIG. 1 is a block diagram that illustrates transformation of the original semiconductor material into a new material manufactured from the original semiconductor material, according to one embodiment of the invention.

FIG. 2 is a block diagram that illustrates the new material configured within a photovoltaic cell, according to one embodiment of the invention.

FIG. 3 is a flow diagram that illustrates an example process for manufacturing a new material from a semiconductor material, according to embodiments of the invention.

### DETAILED DESCRIPTION OF PREFERRED EMBODIMENTS OF THE INVENTION

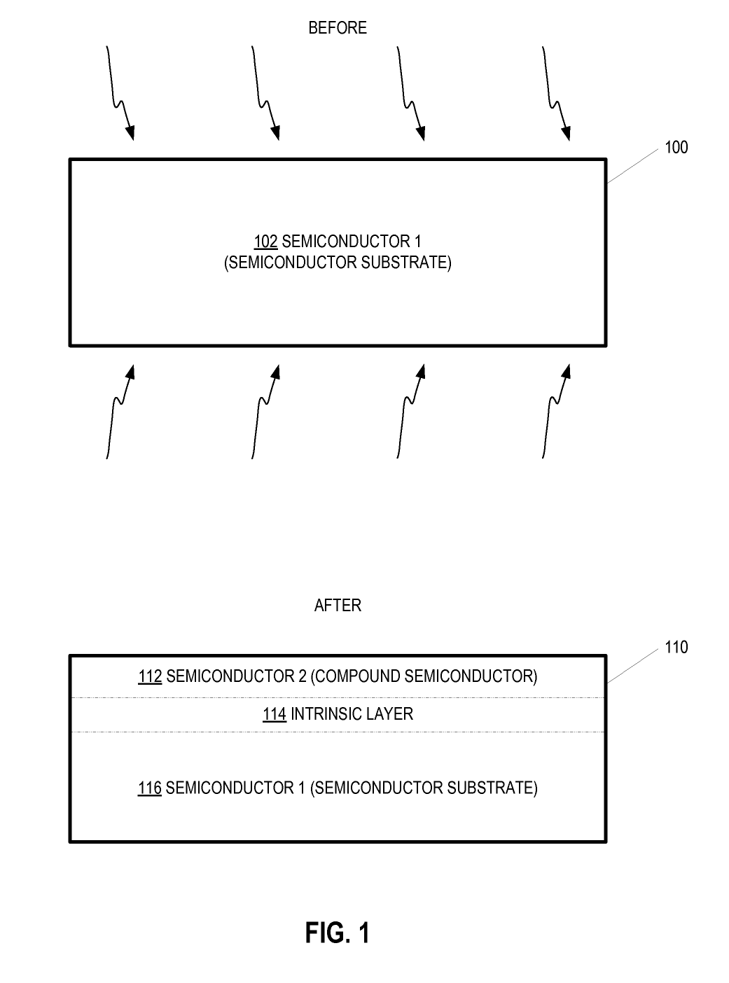

In accordance to one embodiment of the invention, FIG. 1 is a block diagram that illustrates transformation of the original semiconductor material 100 into a new photovoltaic material 110 manufactured from semiconductor material 100, according to one embodiment of the invention.

In some embodiments, semiconductor substrate 100 is a semiconductor wafer, for example, an n-type or p-type single-crystal semiconductor wafer made from silicon (Si) or germanium (Ge). Examples of wafer thicknesses for semiconductor substrate include thicknesses of above 1 μm, typically 500 μm.

Semiconductor substrate 100 contains a target impurity of a desired element. In some embodiments, the target impurity is present in the semiconductor substrate 100 as a natural result of the wafer manufacturing process. In some embodiments, the target impurity is introduced into the wafer by processes such as ion implantation, chemical diffusion, or other such processes for introducing impurities into a semiconductor wafer. In some embodiments, for example, for a silicon or germanium substrate, the target impurity is carbon. In some embodiments, for example, for a germanium substrate, the target impurity is silicon.

In this embodiment, photovoltaic material 110 is fabricated in one annealing process. By annealing the semiconductor wafer, or substrate (semiconductor 1), the impurity contained in the wafer will interact with the primary element in substrate 100 and form a layer 112 of a compound semiconductor surface (semiconductor 2) of photovoltaic material 110 composed of a compound of the primary element and the impurity, for example, silicon carbide (SiC). Other examples of photovoltaic material 110 composition are as follows:

TABLE 1
Photovoltaic material construction possibilities

| | | Semiconductor 2 |
|---|---|---|
| Semiconductor 1 | | (compound |
| (substrate) | Impurity | semiconductor) |
| Silicon (Si) | Carbon (C) | Silicon carbide (SiC) |
| Germanium (Ge) | Carbon (C) | Germanium carbon (Ge₁₋ₓCₓ) |
| Germanium (Ge) | Silicon (Si) | Germanium silicon (Ge₁₋ₓSiₓ) |

Photovoltaic properties is obtained when the band gap of layer 116 of the semiconductor 1, or substrate, is smaller than the band gap of layer 112 of the compound semiconductor, or semiconductor 2. The semiconductor and compound semiconductor interface creates a junction with photovoltaic properties. In some embodiments, a p-n junction or p-i-n junction formed by this manufacturing technique and process has photovoltaic properties. In some embodiments, an n-n junction, where there is a bandgap difference between layer 112 and layer 116, has the necessary photovoltaic properties to form a photovoltaic cell.

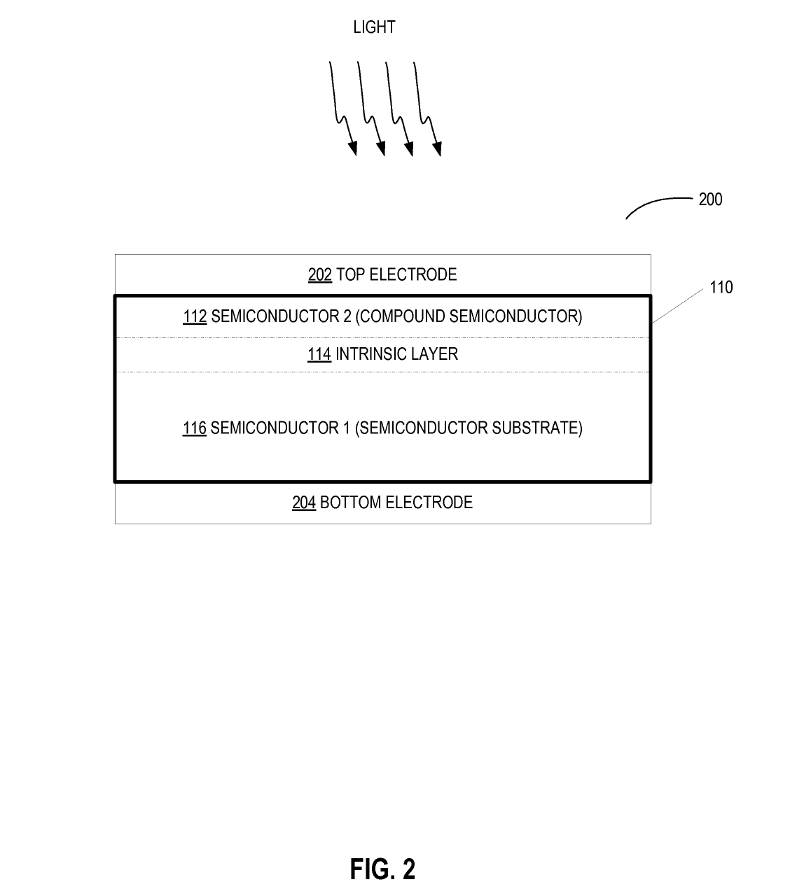

FIG. 2 is a block diagram illustrating a photovoltaic cell 200 having photovoltaic material 110, according to embodiments of the invention. In some embodiments, top electrode 202 is comprised of a transparent conductive oxide (TCO), such as ITO, NiO, ZnO or other TCO available in the market, and is placed adjacent to layer 112 of compound semiconductor material. Semi-transparent or translucent electrode scan also be used depending on the aiming efficiency and cost of the cell.

In some embodiments, bottom electrode 204 is fabricated from aluminum or other metal. Processes for placing bottom electrode 204 adjacent to layer 116 include screen painting, ink-jet printing, physical vapor deposition (sputtering) or other means of deposition. It is understood that a person of skill in the art is not limited to the examples of electrodes described herein, and any suitable electrode composition or type can be used as top and bottom electrode for photovoltaic material 110.

In some embodiments, bottom electrode 204 is an aluminum layer having a thickness above 1 microns. For example, bottom electrode 204 has a thickness of 500 microns.

### Ohmic Electrode

In some embodiments, bottom electrode 204 comprises an electrode with ohmic contacts using metals. In some embodiments, precious metals used for manufacturing an ohmic electrode, for example, gold, silver, or platinum, creates an undesirable Shottcky barrier between the metal and the semiconductor, therefore increasing contact resistivity. The Shottcky barrier may also be observed for other metals such as aluminum and copper, which are also metals normally used in electrical contacts. One approach for ensuring a good ohmic contact (back electrode) between the substrate semiconductor and back electrode includes performing additional steps, such as surface polishing, abrasion, or texturing, before depositing the ohmic contact metal onto photovoltaic material 110, as discussed in copending U.S. application Ser. No. 13/______, filed ______, the contents of which are hereby incorporated by reference as if fully set forth herein. In other cases, the placement of a buffer layer before depositing the metal contact as electrode is performed. An example of a novel buffer layer includes the use of an amorphous silicon carbide (a-SiC), discussed in copending U.S. application Ser. No. 13/______, filed ______, the contents of which are hereby incorporated by reference as if fully set forth herein.

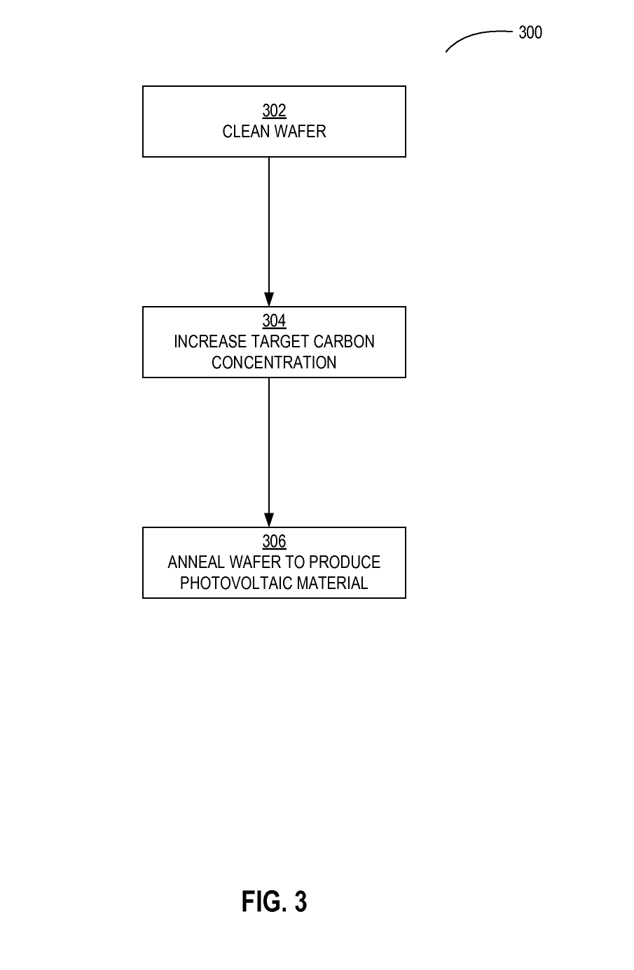

FIG. 3 is a flow diagram that illustrates an example process 300 for manufacturing photovoltaic material 110. At step 302, semiconductor wafer 100 is cleaned to remove unwanted surface contaminants. In particular, a natural oxide film formed at the surface of the wafer is removed. In some embodiments, the wafer is cleaned by dipping the wafer into a solution of hydrofluoric acid, followed by a rinse with water and air drying. This process mainly targets the removal of the natural oxide film formed on the wafer surface.

At step 304, a target impurity is added to semiconductor substrate 100 in a separate process. In some embodiments, a sufficient concentration of the target impurity exists in semiconductor wafer substrate 100 as a normal result of manufacturing semiconductor wafers, and step 304 is omitted from the process. For example, in some embodiments having silicon substrates, an impurity concentration of a carbon is present as a byproduct of wafer fabrication, thus rendering this step unnecessary. In some embodiments, the target impurity is introduced into the wafer by processes such as ion implantation, cementation or other such processes for introducing impurities into a semiconductor wafer. In some embodiments, for example, where semiconductor substrate 100 is a silicon substrate, a target carbon content is above 10 parts per billion (ppb).

At step 306, semiconductor wafer 100 is submitted to an annealing process. The parameters in which the annealing is performed are show in Table 1 below.

TABLE 2
Wafer annealing conditions

| Parameter | Possible Value | Example 1 |
|---|---|---|
| Annealing temperature (K) | 800 to 1700 | 1500 |
| Annealing time (min) | 1 to 600 | 30 |
| Atmosphere | Argon, Nitrogen, or other | Argon |
| | inert gas | |
| Treatment pressure (atm) | Up to 1 | 2 × 10⁻⁴ |

Wafer annealing may be performed in diverse methods. Possible methods include, but are not limited to, convection heated annealing, infrared annealing, laser annealing, induction heated annealing, microwave annealing, or any anneal which can attain the necessary conditions of Table 1.

In step 304, the carbon surface concentration increases by processes, for example, carbon ion implantation, cementation, and carbon diffusion from the semiconductor bulk. In step 306, silicon carbide forms at the silicon surface by chemical reaction of silicon and carbon. The layer of the newly formed compound material is formed as top layer 112 after step 306. Intrinsic semiconductor, for example, intrinsic silicon, is formed below as layer 114. Layer 116 retains the properties of semiconductor substrate 102. Accordingly, step 306 transforms semiconductor wafer 100 into photovoltaic material 110.

Embodiments of the photovoltaic material 110 has the advantages of superior durability, simplified manufacturing process, and improved photovoltaic properties compared to legacy silicon cells, due to the properties of layer 112. In the embodiment resulting in the formation of silicon carbide (SiC), compared to silicon (widely used in legacy solar cells), silicon carbide (SiC) offers excellent thermal conductivity, heat resistance, chemical resistance, a high radiation stability. Layer 112 of SiC also provides much higher physical resistance against the elements for outdoor applications of the photovoltaic cell. Silicon carbide has a wide bandgap, improving photovoltaic properties. In particular, the silicon bandgap is 1.1 eV, compared with the silicon carbide's band gap of approximately 2.3 eV. As solar cell performance is governed in part by the band gap of its components, in the case a photovoltaic cell, the p-n junction, the band gap difference created between the silicon carbide and silicon results in improved photovoltaic performance.

Other features, aspects and objects of the invention can be obtained from a review of the figures and the claims. It is to be understood that other embodiments of the invention can be developed and fall within the spirit and scope of the invention and claims.

The foregoing description of preferred embodiments of the present invention has been provided for the purposes of illustration and description. It is not intended to be exhaustive or to limit the invention to the precise forms disclosed. Various additions, deletions and modifications are contemplated as being within its scope. The scope of the invention is, therefore, indicated by the appended claims rather than the foregoing description. Further, all changes which may fall within the meaning and range of equivalency of the claims and elements and features thereof are to be embraced within their scope.

What is claimed is:

1. A photovoltaic material comprising:
a bulk layer of semiconductor material;
an intermediate layer provided over the bulk layer; and
a top layer provided over the intermediate layer, the top layer comprising a compound semiconductor material,
whereby the bulk layer, the intermediate layer, and the top layer are created by a transformative process on a single-piece semiconductor material, the single-piece semiconductor material having an impurity.

2. The photovoltaic material of claim 1, wherein the transformative process is caused by performing the steps of:
exposing of a top surface of the single-piece semiconductor material to an energy source, whereby the energy source causes heating of a portion of the single-piece semiconductor material; and
ceasing exposure of the top surface of the single-piece semiconductor material to the energy source, whereby the exposing step and the ceasing step cause the single-piece semiconductor material to transform into the structure comprising the bulk layer, the intermediate layer, and the top layer.

3. The photovoltaic material of claim 2, wherein the portion of the single-piece semiconductor material is heated to a temperature of between 800 K and 1700 K.

4. The photovoltaic material of claim 2, wherein the steps of exposing and ceasing occurs in a vacuum.

5. The photovoltaic material of claim 2, wherein the heating of the portion occurs for a duration of 1 to 600 minutes.

6. The photovoltaic material of claim 1, whereby the intermediate layer is substantially equivalent to intrinsic semiconductor.

7. The photovoltaic material of claim 1, wherein the top layer comprises silicon carbide, and single-piece semiconductor material comprises silicon, the silicon having the impurity of carbon.

8. The photovoltaic material of claim 1, wherein the top layer comprises germanium-silicon, and single-piece semiconductor material comprises germanium, the germanium having the impurity of silicon.

9. The photovoltaic material of claim 1, wherein the band gap of the bulk layer is smaller than the band gap the top layer.

10. The photovoltaic material of claim 1, wherein the top layer, the intermediate layer, and the bulk layer form any one of a p-i-n junction, a p-n junction, or an n-n junction.

11. The photovoltaic material of claim 1, wherein the photovoltaic material produces photovoltaic effects when exposed to light.

12. A photovoltaic device using the photovoltaic material according to claim 1, the photovoltaic device comprising:
the photovoltaic material;
a bottom electrode provided under the photovoltaic material; and
a top electrode provided over the photovoltaic material.

13. A method for manufacturing a single-piece photovoltaic, comprising transformative process that is caused by performing the steps of:
exposing of a top surface of a single-piece semiconductor material to an energy source, whereby the energy source causes heating of a portion of the single-piece semiconductor material; and
ceasing exposure of the top surface of the single-piece semiconductor material to the energy source, whereby the exposing step and the ceasing step cause the single-piece semiconductor material to transform into a structure comprising:
a bulk layer of semiconductor material;
an intermediate layer provided over the bulk layer; and
a top layer provided over the intermediate layer, the top layer comprising a compound semiconductor material.

14. The method of claim 13, wherein the portion of the single-piece semiconductor material is heated to a temperature of between 800 K and 1700 K.

15. The method of claim 13, wherein the steps of exposing and ceasing occurs in a vacuum.

16. The method of claim 13, wherein the heating of the portion occurs for a duration of 1 to 600 minutes.

17. The method of claim 13, whereby the intermediate layer is substantially equivalent to intrinsic semiconductor.

18. The method of claim 13, wherein the top layer comprises silicon carbide, and single-piece semiconductor material comprises silicon, the silicon having the impurity of carbon.

19. The method of claim 13, wherein the top layer comprises germanium-silicon, and single-piece semiconductor material comprises germanium, the germanium having the impurity of silicon.

20. The method of claim 13, wherein the band gap of the bulk layer is smaller than the band gap the top layer.

21. The method of claim 13, wherein the top layer, the intermediate layer, and the bulk layer form any one of a p-i-n junction, a p-n junction, or an n-n junction.

22. The method of claim 13, wherein the photovoltaic material produces photovoltaic effects when exposed to light.

23. A photovoltaic material comprising:
a bulk layer of silicon wafer;
an intermediate layer provided over the bulk layer; and
a top layer provided over the intermediate layer, the top layer comprising a compound semiconductor material, the compound semiconductor material comprising SiC,
whereby the bulk layer, the intermediate layer, and the top layer are created by a transformative process on a single-piece semiconductor material having a concentration of carbon, the transformative process is caused by performing the steps of:
exposing of a top surface of the single-piece semiconductor material to an energy source, whereby the energy source causes heating of a portion of the single-piece semiconductor material; and
ceasing exposure of the top surface of the single-piece semiconductor material to the energy source, whereby the exposing step and the ceasing step cause the single-piece semiconductor material to transform into the structure comprising the bulk layer, the intermediate layer, and the top layer comprising SiC.
